(19) United States
(12) Patent Application Publication
(10) Pub. No.: US 2012/0305970 A1
(43) Pub. Date: Dec. 6, 2012

(54) LIGHT EMITTING DEVICE PACKAGE AND MANUFACTURING METHOD THEREOF

(76) Inventor: Hyung Kun KIM, Suwon (KR)

(21) Appl. No.: 13/484,965

(22) Filed: May 31, 2012

(30) Foreign Application Priority Data
Jun. 2, 2011 (KR) 10-2011-0053239

(51) Int. Cl. H01L 33/44; H01L 33/58

(52) U.S. Cl. 257/98; 438/29; 257/E33.061; 257/E33.073; 257/E33.072

(57) ABSTRACT

There is provided a light emitting device package including a substrate having a cavity therein; alight emitting device mounted on a bottom surface of the cavity; a first wavelength conversion part including a first phosphor for a wavelength conversion of light emitted from the light emitting device and covering the light emitting device within the cavity; and a second wavelength conversion part including a second phosphor allowing for emission of light having a wavelength different to that of the first phosphor and formed as a sheet on the first wavelength conversion part.

### CROSS-REFERENCE TO RELATED APPLICATIONS

This application claims the priority of Korean Patent Application No. 10-2011-0053239 filed on Jun. 2, 2011, in the Korean Intellectual Property Office, the disclosure of which is incorporated herein by reference.

### BACKGROUND OF THE INVENTION

1. Field of the Invention

The present invention relates to a light emitting device package and a method of manufacturing the same.

2. Description of the Related Art

A light emitting diode (LED) is a semiconductor device capable of emitting light of various colors, due to electron-hole recombination occurring at a p-n junction when a current is supplied thereto, by using compound semiconductor materials such as GaAs, AlGaAs, GaN, InGaN, AlGaInP and the like as a light source.

LEDs are environmentally-friendly, have fast response rates on the level of several nano seconds so as to be effective for a video signal stream, and are capable of being impulsively driven.

Moreover, LEDs have a color gamut of 100% or higher and the luminance and color temperature thereof may be easily adjusted according to the amount of light emitted from red, green and blue LEDs. Therefore, LEDs have been actively employed as light emitting devices in various types of light emitting apparatuses.

Particularly, of late, LEDs using nitride-based semiconductors are being employed as white light sources, so they are widely applied in various fields requiring white light sources such as in the case of a keypad, a backlight, a traffic light, airport runway lights, a general lighting apparatus and the like.

The factors determining the characteristics of LEDs are color, light speed, distribution of luminous intensity, and the like.

These characteristics are primarily determined by compound semiconductor materials used in LEDs, and are secondarily affected by a package structure and a phosphor application method.

In recent years, the primary characteristics of an LED chip itself have been rapidly enhanced, but at present, the development thereof has reached a certain technological level of development and the pace of development is therefore slowing.

For this reason, an improvement of the secondary characteristics is required to develop a package having high reliability by improving light speed and the distribution of luminous intensity.

In particular, in a case of an LED lighting apparatus, there is an increased demand for improved color rendering. Recently, the development of a product having a high color rendering index (CRI) has been required, and a white LED chip and a red LED chip have been mainly used therein.

However, when the white LED chip and the red LED chip are used at the same time, it is necessary to configure a separate circuit through feedback with respect to each of the white LED chip and the red LED chip, whereby productivity may be reduced.

The characteristics of light emitted to the outside are determined according to the thickness of red and green phosphor layers and the amount of phosphor materials applied. In the related art, phosphor application thickness and amount have been adjusted for each product, and accordingly, non-uniform thicknesses thereof have been caused to thereby deteriorate product reliability and make the characteristics of light different in each product, causing a decline in product quality.

Particularly, when the power of chips being mounted is different, it is necessary to adjust the characteristics of light. In the related art, whenever the power of chips has been altered, it has been cumbersome to adjust both the amount of phosphors in a red second wavelength conversion part and the amount of phosphors in a green second wavelength conversion part.

In the case of the application of phosphor materials by a dispensing process, the thickness of the outermost phosphor layer may be entirely uneven, so color deviation in light emitted from the LED chip may occur, resulting in a reduction of product reliability. Accordingly, a highly advanced phosphor application technique is required, thereby resulting in a low yield, and thus a product manufacturing time and manufacturing costs may be increased.

### SUMMARY OF THE INVENTION

An aspect of the present invention provides a method of manufacturing a light emitting device package having a color rendering index (CRI) of 90 or above, as well as improved correlated color temperature (CCT).

An aspect of the present invention also provides a light emitting device package in which the thickness of a first wavelength conversion part and a phosphor applied to a light emitting device is uniform and easily adjusted to thereby reduce color deviation in light emitted from the light emitting device, whereby the reliability thereof may be improved and the manufacturing time and costs thereof may be reduced.

According to an aspect of the present invention, there is provided a light emitting device package including: a substrate having a cavity therein; a light emitting device mounted on a bottom surface of the cavity; a first wavelength conversion part including a first phosphor for a wavelength conversion of light emitted from the light emitting device and covering the light emitting device within the cavity; and a second wavelength conversion part including a second phosphor allowing for emission of light having a wavelength different to that of the first phosphor and formed as a sheet on the first wavelength conversion part.

The first phosphor of the first wavelength conversion part may include a red phosphor, and the second phosphor of the second wavelength conversion part may include a green phosphor.

The first wavelength conversion part may be disposed within the cavity, and the second wavelength conversion part may be exposed outside of an upper portion of the cavity.

The cavity may have a stepped double layer structure, and the first wavelength conversion part may be provided in a lower layer of the cavity and the second wavelength conversion part may be provided in an upper layer of the cavity.

The light emitting device may be a blue light emitting diode chip.

The second wavelength conversion part may have a refraction index lower than that of the first wavelength conversion part.

The second wavelength conversion part may have a downwardly concave upper surface.

The second wavelength conversion part may have an upwardly convex upper surface.

The first wavelength conversion part and the second wavelength conversion part may have an adhesive resin part provided therebetween.

The adhesive resin part may have a refraction index lower than that of the first wavelength conversion part.

The second wavelength conversion part may have a plurality of protrusions on an upper surface thereof.

The second wavelength conversion part may have a plurality of droplet-shaped light extraction enhancing parts on an upper surface thereof.

The light extraction enhancing parts may be formed of a green phosphor or a transparent silicon.

The second wavelength conversion part may have an etched part formed by etching an upper edge thereof.

The first wavelength conversion part may include silicon, epoxy or silica.

The cavity may have an inclined inner wall.

The cavity may have an inner wall serving as a light reflective surface.

The inner wall of the cavity may be further coated with a reflective material.

The light emitting device package may further include a lens part provided on the substrate while covering the second wavelength conversion part.

According to another aspect of the present invention, there is provided a method of manufacturing a light emitting device package, the method including: preparing a substrate having a cavity therein and mounting a light emitting device within the cavity; forming a first wavelength conversion part within the cavity by mixing a first phosphor with a transparent resin such that the first wavelength conversion part covers the light emitting device and converts a wavelength of light emitted from the light emitting device; forming a second wavelength conversion part on the first wavelength conversion part by coating a sheet-type phosphor film including a second phosphor allowing for emission of light having a wavelength different to that of the first phosphor; and hardening the first and second wavelength conversion parts at the same time.

The first wavelength conversion part may include a red phosphor, and the second wavelength conversion part may include a green phosphor.

The cavity may be formed in an upper surface of the substrate by a hole making process using drilling.

The cavity may be formed by stacking a second sub-substrate having a central hole portion on a flat upper surface of a first sub-substrate.

The cavity may have a stepped double layer structure formed by stacking a second sub-substrate having a central hole portion on a flat upper surface of a first sub-substrate and stacking a third sub-substrate having a central hole portion greater than that of the second sub-substrate on the second sub-substrate.

The first wavelength conversion part may be dispensed to a lower layer of the cavity formed by the second sub-substrate, and the sheet-type second wavelength conversion part may be coated to cover the first wavelength conversion part in an upper layer of the cavity formed by the third sub-substrate.

The first wavelength conversion part may be formed within the cavity, and the second wavelength conversion part may be disposed outside the cavity while covering an upper surface of the first wavelength conversion part.

The light emitting device may be a blue light emitting diode chip.

The forming of the second wavelength conversion part may include causing an upper surface of the phosphor film to be downwardly concave.

The forming of the second wavelength conversion part may include causing an upper surface of the phosphor film to be upwardly convex.

The method may further include forming an adhesive resin part on the first wavelength conversion part prior to the forming of the second wavelength conversion part.

The method may further include forming a plurality of protrusions by patterning an upper surface of the second wavelength conversion part after the forming of the second wavelength conversion part.

The method may further include forming a plurality of light extraction enhancing parts having a droplet shape on an upper surface of the second wavelength conversion part by a coating process after the forming of the second wavelength conversion part.

The method may further include forming an etched part by etching an upper edge of the second wavelength conversion part by a UV treatment after the forming of the second wavelength conversion part.

The method may further include providing a lens part on the substrate.

### BRIEF DESCRIPTION OF THE DRAWINGS

The above and other aspects, features and other advantages of the present invention will be more clearly understood from the following detailed description taken in conjunction with the accompanying drawings, in which:

FIG. 1 is a cross-sectional view of a light emitting device package according to an embodiment of the present invention;

FIG. 2 is a perspective view of the light emitting device package of FIG. 1;

FIG. 3 is a cross-sectional view of a light emitting device package in which a lens part has a different shape to the embodiment of FIG. 1;

FIG. 4 is a cross-sectional view of a light emitting device package having a second wavelength conversion part outside of a cavity according to another embodiment of the present invention;

FIG. 5 is a cross-sectional view of a light emitting device package in which a lens part has a different shape to the embodiment of FIG. 4;

FIG. 6 is a cross-sectional view of a light emitting device package having an inclined cavity according to another embodiment of the present invention;

FIG. 7 is a cross-sectional view of a light emitting device package in which a lens part has a different shape to the embodiment of FIG. 6;

FIG. 8 is a cross-sectional view of a light emitting device package having a multilayer cavity according to another embodiment of the present invention;

FIG. 9 is a cross-sectional view of a light emitting device package in which a lens part has a different shape to the embodiment of FIG. 8;

FIG. 10 is a cross-sectional view of a light emitting device package including a second wavelength conversion part having a patterned upper surface according to another embodiment of the present invention;

FIG. 11 is a cross-sectional view of a light emitting device package in which a lens part has a different shape to the embodiment of FIG. 10;

FIG. 12 is a cross-sectional view of a light emitting device package including a second wavelength conversion part having droplet-shaped light extraction enhancing parts provided on an upper surface thereof according to another embodiment of the present invention;

FIG. 13 is a cross-sectional view of a light emitting device package in which a lens part has a different shape to the embodiment of FIG. 12; and

FIG. 14 is a cross-sectional view of a light emitting device package including a second wavelength conversion part having an etched part provided on an upper edge thereof according to another embodiment of the present invention.

### DETAILED DESCRIPTION OF THE INVENTION

Embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art.

In the drawings, the shapes and sizes of elements may be exaggerated for clarity, and the same reference numerals will be used throughout to designate the same or like elements.

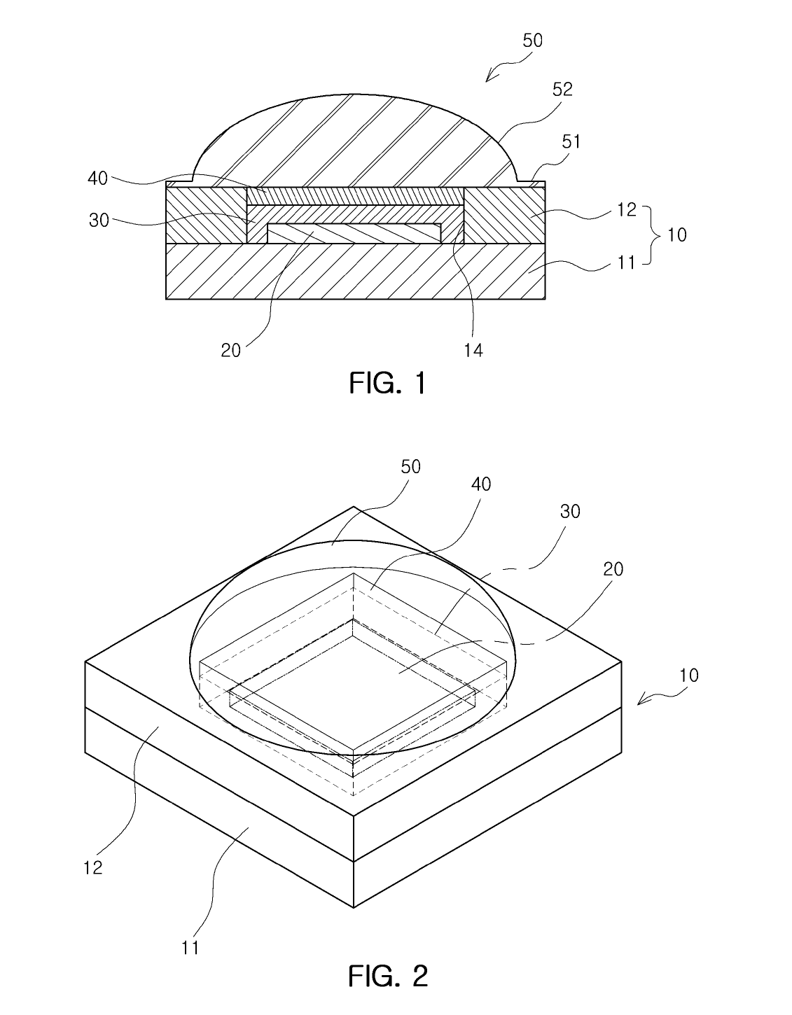

With reference to FIGS. 1 and 2, a light emitting device package according to an embodiment of the present invention includes a substrate 10 having a cavity 14 formed therein, a light emitting device 20 mounted on a bottom surface of the cavity 14 of the substrate 10, a first wavelength conversion part 30 dispensed to cover the light emitting device 20 within the cavity 14, and a second wavelength conversion part 40 coated on the first wavelength conversion part 30 to cover the first wavelength conversion part 30.

The substrate 10, a type of printed circuit board (PCB), may be a ceramic substrate having high thermal conductivity efficiency and easily releasing heat, generated during the operation of the light emitting device 40, outwardly. However, the invention is not limited thereto.

That is, the substrate 10 may be formed of an organic resin material containing epoxy resin, triazine resin, silicone resin, polyimide resin, or the like, other organic resin materials, a ceramic material such as AlN, Al₂O₃ or the like, or metals and metallic compounds.

In addition, the substrate 10 may be formed as a single body and have the cavity 14 formed by a hole making process such as drilling in a vertical direction. In the present embodiment, however, in order to secure various conductive patterns and facilitate the forming of the cavity 14, a second sub-substrate 12 having a central hole portion is stacked on a flat upper surface of a first sub-substrate 11 and fixed thereto using an adhesive or the like, whereby the substrate 10 is prepared to have the cavity 14.

The shape of the cavity 14 of the substrate 10 is determined by the shape of the central hole portion of the second sub-substrate 12. The cavity 14 of the substrate 10 may have a circular shape which is easily processed. However, the invention is not limited thereto. The cavity may have various shapes such as a square shape, a quadrangular shape or the like, in consideration of the type of the package, the shape of the light emitting device and the like.

The substrate 10 provides a space such that the light emitting device 20 is mounted therein. Electrodes (not shown) of various shapes may be provided in various locations such as on upper and lower surfaces of the substrate 10, between the first and second sub-substrates 11 and 12, or the like, such that they transmit electrical signals to the light emitting device 20.

The light emitting device 20 may be electrically connected to an electrode using a connective member such as a wire. The light emitting device 20 according to this embodiment may be connected to the electrode formed on the substrate 10 by a flip-chip bonding method or the like. Without being limited thereto, such an electrical connection may have various shapes.

The light emitting device 20 according to this embodiment may employ any device as long as it can be used as a light source. A light emitting diode (LED) may be employed in consideration of the compactness and high light emission efficiency of the light source.

An LED is a light source producing light when a voltage is applied thereto. It is usually used in an apparatus, such as a backlight unit, requiring a white light source.

For such an LED, a white LED chip is usually used, but red, green and blue LED chips may also be used to thereby selectively emit light having colors corresponding thereto.

Also, red, green and blue light emitted therefrom may be mixed to produce white light. The red, green and blue LED chips may be installed and different voltages may be applied thereto so that light of a desired color, other than red, green and blue light, may be produced.

According to the present embodiment, in order to produce white light, a blue LED chip may be used as the light emitting device 20 and a mixed resin containing a transparent silicon and a red phosphor may be used for the first wavelength conversion part 30 encapsulating the light emitting device 20.

The second wavelength conversion part 40 positioned over the first wavelength conversion part 30 may include a green phosphor in order to achieve enhanced white light. The second wavelength conversion part 40 may include only the green phosphor or both the green phosphor and a transparent silicon.

Light produced in the light emitting device 20 transits the first wavelength conversion part 30 including the red phosphor and the second wavelength conversion part 40 including the green phosphor sequentially, to thereby produce white light.

Here, the thickness of the second wavelength conversion part 40 and the ratio of the phosphors may be altered to thereby adjust a color temperature of light, whereby different color temperatures may be obtained.

Here, the thickness of the second wavelength conversion part 40 may be 100 μm or less allowing for optimum light efficiency, taking into consideration a refraction index of light and the like obtained by several light measurement tests.

Meanwhile, the second wavelength conversion part 40 usually has a flat upper surface. However, the second wavelength conversion part 40 may have a downwardly concave upper surface or an upwardly convex upper surface, taking into consideration an orientation angle of light and the like, as necessary.

Here, the radius of curvature of the second wavelength conversion part 40 may be set by taking into consideration the power of the light emitting device 20, the size of the cavity 14 and the like.

Meanwhile, the cavity 14 of the substrate 10 has a width and a depth of the bottom surface thereof determined by taking into consideration the size of the light emitting device 20 mounted therein and the thickness of the second wavelength conversion part 40.

In general, an LED chip used as the light emitting device 20 in the present embodiment is a cube-type light source, allowing light to be emitted from individual surfaces thereof.

Since a large amount of light is produced from side surfaces of the LED chip, a reflective member may be disposed to correspond to the side surfaces of the light emitting device 20 in order to reduce light loss, such that the path of light produced from the side surfaces of the light emitting device 20 is altered to be guided upwardly.

To enable this, the height of an inner wall of the cavity 14 is adjusted according to the size of the light emitting device 20, such that the inner wall of the cavity 14 may serve as a light reflective surface for reflecting light emitted from the side surfaces of the light emitting device 20.

That is, light emitted from the light emitting device 20 is reflected by the inner wall of the cavity 14, and its path is altered to be guided forward, whereby light loss may be minimized.

Here, in order to further increase the reflectivity of the light of the light emitting device 20, a coating film (not shown) formed of a metallic reflective material such as aluminum may be further formed on the inner wall of the cavity 14.

The first wavelength conversion part 30 may be formed of a light transmissive resin. Prior to the forming of the second wavelength conversion part 40, the first wavelength conversion part 30 may be formed to encapsulate the light emitting device 20 in order to improve external light extraction efficiency by protecting the light emitting device 20 and allowing for refraction index matching of the light emitting device 20 with the outside.

Further, the first wavelength conversion part 30 allows the second wavelength conversion part 40, sensitive to heat, to be spaced apart from heat generated in the light emitting device 20, thereby preventing discoloration of the second wavelength conversion part 40 caused by heat during the operation of the light emitting device 20.

The first wavelength conversion part 30 may be formed of a resin having high transparency, such as silicon, epoxy or silica, such that the first wavelength conversion part 30 allows the light produced in the light emitting device 20 to pass therethrough while minimizing light loss.

Also, the first wavelength conversion part 30 may include a phosphor material in order to convert monochromatic light to white light or the like by the wavelength conversion of the light emitted from the light emitting device 20.

In addition, the first wavelength conversion part 30 may further include an ultraviolet absorbent in order to absorb ultraviolet rays emitted from the light emitting device 20.

A lens part 50 may be provided on the substrate 10 while covering the cavity 14, to protect the second wavelength conversion part 40, the wire and the like and obtain various radiation patterns and various light speeds in the light emitting device 20.

The lens part 50 may include a base plate 51 fixedly attached to the substrate 10 by a silicon molding, and a light transmissive part 52 formed at the center of the base plate 51. The light transmissive part 52 may be formed of a transparent or translucent material, preferably of silicon or silica, such that the light transmissive part 52 allows light emitted from the light emitting device 20 to pass therethrough and be diffused upwardly.

The lens part 50 may be formed by directly dispensing the transparent or translucent material to the second sub-substrate 12 using a mold. In the case of a large-sized lens part, the lens part may be separately manufactured and attached to the second sub-substrate 12 by a bonding method or the like.

In a case in which the light emitting device 20 is an LED chip having straight ability, the light transmissive part 52 of the lens part 50 may be upwardly convex when attached to the second sub-substrate 12 in order to extensively diffuse light of the LED chip, which is a point light source, and to achieve light emission uniformity.

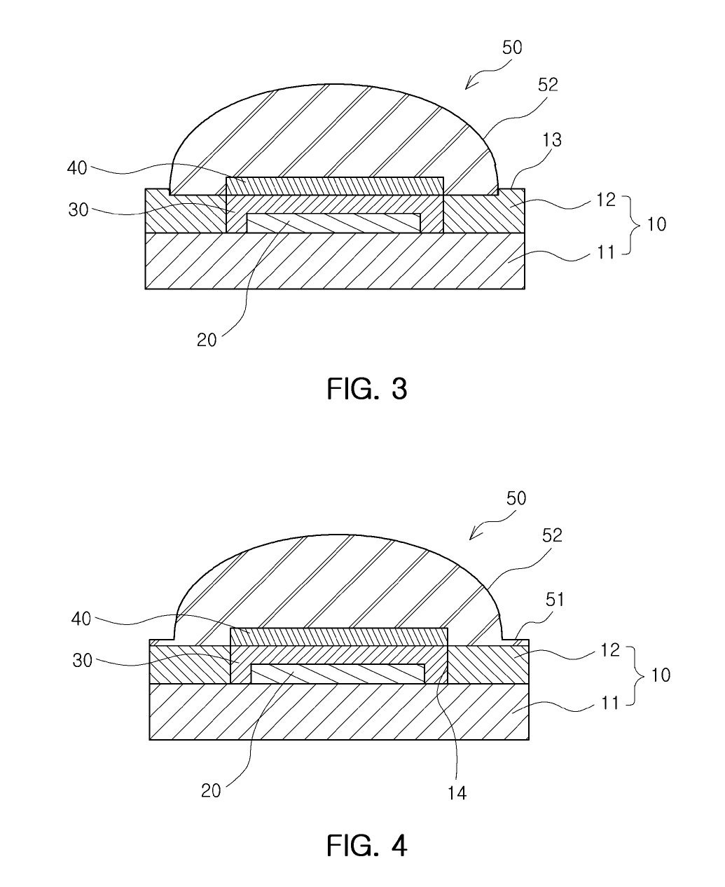

Here, as shown in FIG. 3, the base plate 51 of the lens part 50 may not be formed. Instead, a protruding part 13 having a predetermined height may be formed on an edge portion of an upper surface of the second sub-substrate 12 and a lower portion of the light transmissive part 52 of the lens part 50 may be fixedly attached to an inner wall of the protruding part 13.

Hereinafter, a light emitting device package according to another embodiment of the invention is described with reference to FIG. 4.

In this embodiment, the height of the second sub-substrate 12 is lower than that of the second sub-substrate of the previous embodiment, and the first wavelength conversion part 30 is dispensed to cover the light emitting device 20 within the cavity 14.

The upper surface of the first wavelength conversion part 30 is disposed to be parallel to the upper surface of the cavity 14. The second wavelength conversion part 40 is formed on the upper surface of the first wavelength conversion part 30 to be exposed outwardly of the cavity 14. Since the second wavelength conversion part 40 is formed outside the cavity 14, the forming thereof is facilitated.

The lens part 50 may be further provided on the substrate 10 to cover the cavity 14 and the second wavelength conversion part 40 and obtain various radiation patterns and various light speeds in the light emitting device 20.

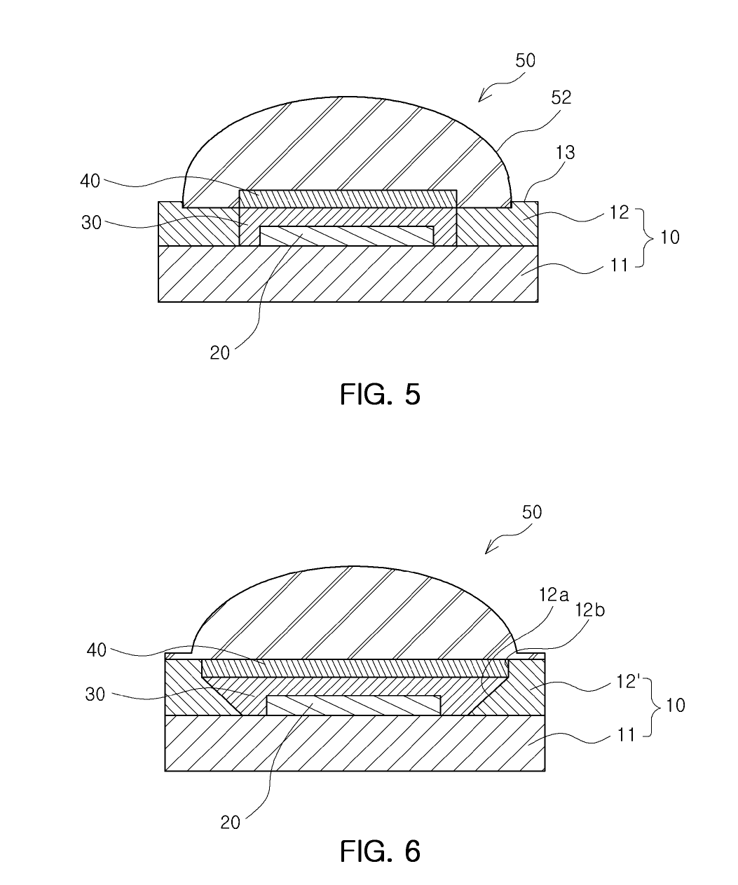

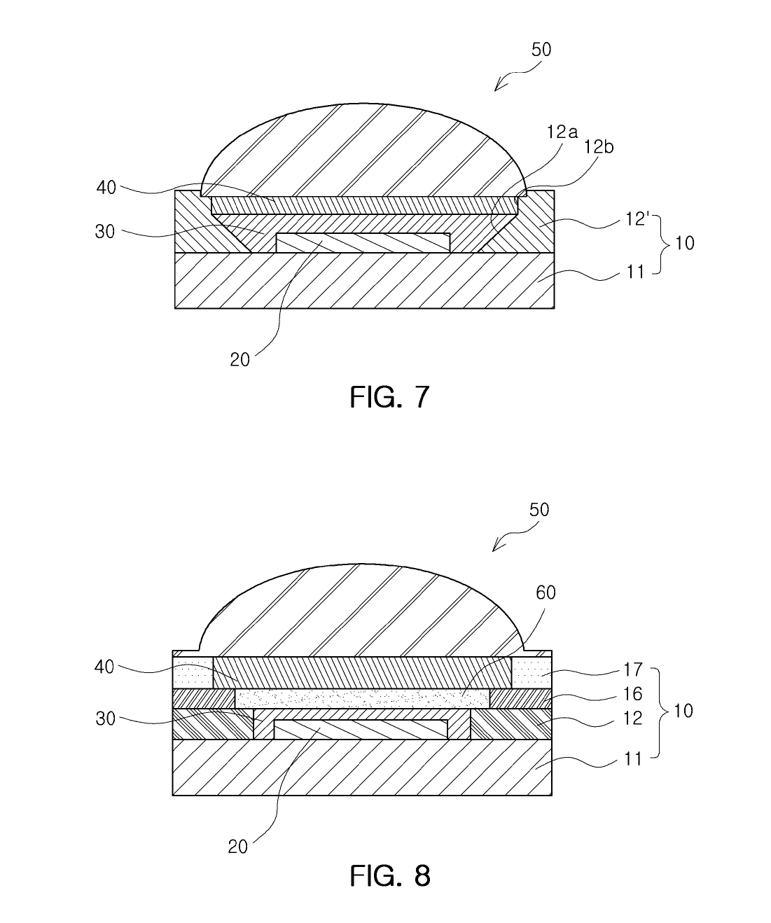

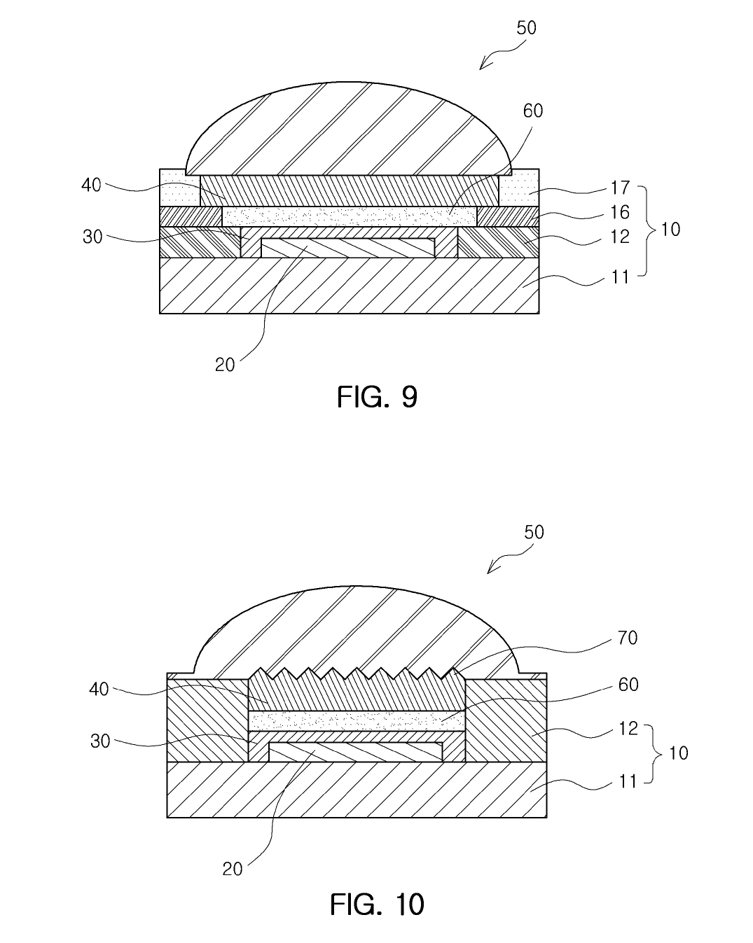

Here, as shown in FIG. 5, the base plate 51 of the lens part 50 may not be formed. Instead, the protruding part 13 having a predetermined height may be formed on the edge portion of the upper surface of the second sub-substrate 12 and the lower portion of the light transmissive part 52 of the lens part 50 may be fixedly attached to the inner wall of the protruding part 13.

Meanwhile, the inner wall of the cavity 14 may be vertical, or may be inclined by the central hole portion, i.e., an inclined lower inner wall 12a of the second sub-substrate 12′ as shown in FIG. 6 such that it may effectively adjust the amount of light reflected forward and dispersed laterally considering that a lighting area of the light emitted from the light emitting device 20 is changed according to the degree of inclination of the inner wall of the cavity 14.

The degree of inclination of the lower inner wall 12a may be changed within various ranges, considering the characteristics of the light emitting device 20, the orientation angle of light, and the like, that is, it may be selected to demonstrate desired light characteristics according to the intended use of a product.

The degree of inclination of the inner wall of the cavity 14 may be 30° to 60°, and more preferably, 45°.

Here, a reflective layer, such as a coating film (not shown) formed of a metallic material such as aluminum or the like, may further be formed on the inner wall of the cavity 14 such that reflectivity of light transmitted to the light emitting device 20 may be further enhanced.

In the present embodiment, an upper inner wall 12b of the second sub-substrate 12′ is formed vertically in the upper portion of the cavity 14 having the second wavelength conversion part 40 formed therein. However, the upper inner wall 12b may also be inclined according to the shape of the second wavelength conversion part 40 as necessary.

FIG. 8 shows a light emitting device package according to another embodiment of the invention. The light emitting device package according to this embodiment may have a multilayer structure in which the substrate 10 includes a plurality of sub-substrates 12, 16 and 17 having central hole portions whose diameters gradually increase in an upward direction, such that the cavity 14 has a stepped multilayer structure. Meanwhile, a detailed description of the same elements as described in the previous embodiment will be omitted.

The first wavelength conversion part 30 may be formed in a lower sub-substrate 12 disposed on a flat base substrate, and the second wavelength conversion part 40 formed as different colored sheets may be formed in intermediate and upper sub-substrates 16 and 17. Here, the different colored sheets may be selected from a red second wavelength conversion part, a green second wavelength conversion part, an orange second wavelength conversion part or a yellow second wavelength conversion part. Alternatively, two or more identically colored second wavelength conversion parts may be repeatedly formed.

If necessary, a single second wavelength conversion part may be formed by mixing phosphor materials having a plurality of colors. In the case in which the different colored sheets of the second wavelength conversion part 40 are formed in the intermediate and upper sub-substrates 16 and 17, light speed and color rendering index (CRI) may be enhanced.

The yellow second wavelength conversion part may be formed of a phosphor material selected from a YAG-based phosphor, a TAG-based phosphor, or a silicate-based phosphor (Sr₂SiO₁:Eu); however, the invention is not limited thereto.

Here, the second wavelength conversion part 40 may further include a diffusion material in order to smoothly diffuse light, in addition to the phosphor material for the wavelength conversion of light emitted from the light emitting device 20.

The inner wall of the cavity 14 may be inclined at various angles such that the amount of light reflected forward and dispersed laterally may be effectively adjusted, considering that a lighting area of the light emitted from the light emitting device 20 is changed according to the degree of inclination of the inner wall of the cavity 14.

Here, the inner wall of the cavity 14 may be formed such that the individual sub-substrates 12, 16 and 17 have different angles of inclination, taking an orientation angle of the light reflected forward into consideration.

In a case in which the cavity 14 may have a stepped double layer structure, the first wavelength conversion part may be dispensed to a lower layer of the cavity 14, and the second wavelength conversion part may be coated in an upper layer of the cavity 14.

In a case in which the cavity 14 may include three stepped layers by the sub-substrates 12, 16 and 17 as illustrated in the present embodiment, the first wavelength conversion part 30 may be dispensed to cover the light emitting device 20 in the lower sub-substrate 12 and an adhesive resin part 60 may be formed in the intermediate sub-substrate 16.

Here, the adhesive resin part 60 may be formed of silicon or the like. The refraction index of the adhesive resin part 60 is lower than that of the first wavelength conversion part 30 including the red phosphor, thereby allowing light to be guided upwardly without light loss. If necessary, the adhesive resin part 60 may be formed after the hardening of the first wavelength conversion part 30.

Then, the sheet-type second wavelength conversion part 40 may be coated on the adhesive resin part 60 to be disposed in the upper sub-substrate 17.

With reference to FIG. 10, a plurality of protrusions 70 may be formed by patterning the upper surface of the second wavelength conversion part 40 such that light extraction efficiency is enhanced and a light diffusion angle is adjusted.

Here, the cavity 14 may have a single layer structure or a multilayer structure. Also, whether to form the adhesive resin part or not may be decided.

In the present embodiment, the adhesive resin part 60 is formed on the first wavelength conversion part 30 and the second wavelength conversion part 40 is formed on the adhesive resin part 60. However, the invention is not limited thereto. Without the forming of the adhesive resin part 60, the second wavelength conversion part 40 may be directly formed on the first wavelength conversion part 30.

In the present embodiment, the lens part 50 may be provided on the substrate 10 to cover the stepped cavity 14 and the second wavelength conversion part 40 and obtain various radiation patterns and various light speeds in the light emitting device 20.

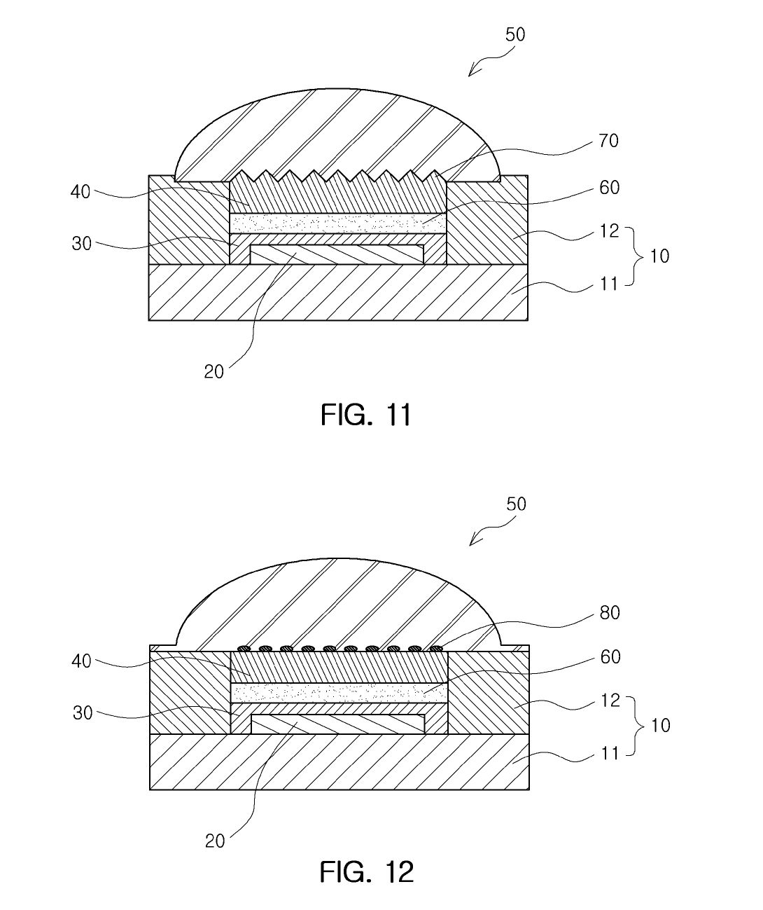

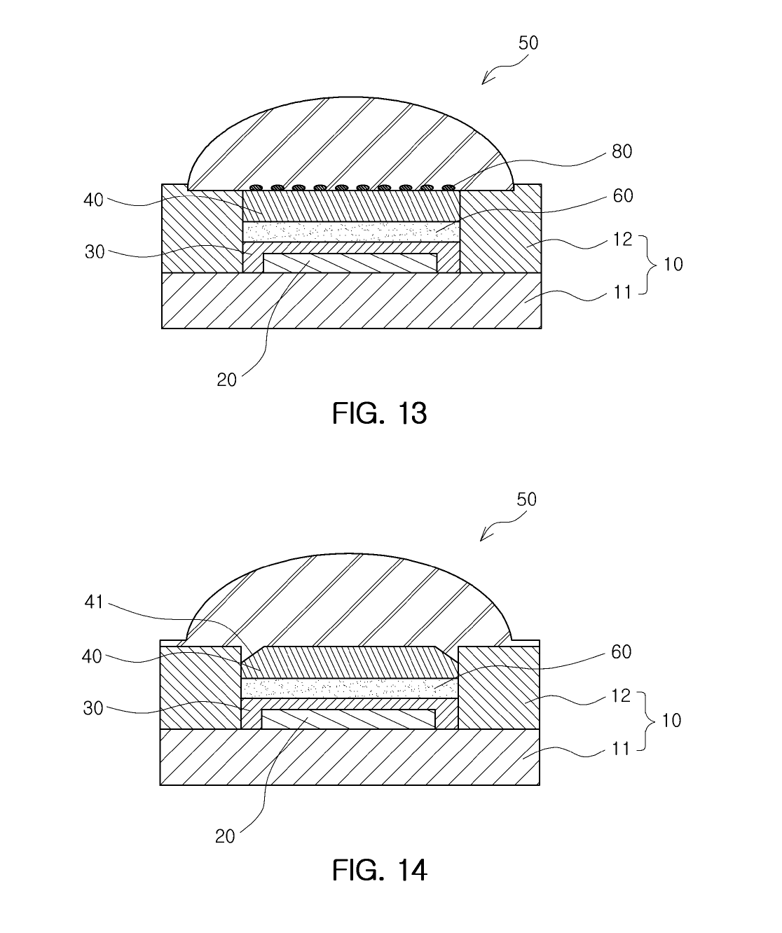

The lens part 50 may be installed on the substrate 10 by including the base plate 51 fixedly attached on the substrate 10 by a silicon molding. Alternatively, as shown in FIG. 11, without the forming of the base plate 51 of the lens part 50, the protruding part 13 having a predetermined height may be formed on the edge portion of the upper surface of the second sub-substrate 12 and the lower portion of the light transmissive part 52 of the lens part 50 may be fixedly attached to the inner wall of the protruding part 13.

With reference to FIG. 12, a plurality of light extraction enhancing parts 80 having a droplet shape may be formed on the upper surface of the second wavelength conversion part 40 while having a predetermined interval therebetween, such that light extraction efficiency is enhanced and a light diffusion angle is adjusted.

The light extraction enhancing part 80 may be formed of a resin having high viscosity and include a green phosphor therein, or may be formed of only a green phosphor.

Also, the light extraction enhancing part 80 may be formed of only a transparent silicon with the exception of a phosphor material. In this case, the light extraction enhancing part 80 may be formed of the same material as that of the first wavelength conversion part 30.

According to this embodiment, the lens part 50 may be provided on the substrate 10 to cover the stepped cavity 14 and the second wavelength conversion part 40 and obtain various radiation patterns and various light speeds in the light emitting device 20.

In the present embodiment, the adhesive resin part 60 is formed on the first wavelength conversion part 30 and the second wavelength conversion part 40 is formed on the adhesive resin part 60. However, the invention is not limited thereto. Without the forming of the adhesive resin part 60, the second wavelength conversion part 40 may be directly formed on the first wavelength conversion part 30.

FIG. 14 shows a light emitting device package according to another embodiment of the invention.

Since the second wavelength conversion part 40 formed on the upper portion of this light emitting device package has photosensitivity, a portion thereof may be etched by ultraviolet (UV) light or the like to thereby form an etched part 41.

Here, the photosensitivity of a photosensitive area indicates that a photosensitizer coated on a film, printing paper or the like reacts with respect to individual colors of light. Various colors of light have different respective wavelengths, and some wavelengths may be absorbed and sensitized, while other wavelengths may not be absorbed according to a type of photosensitizer. That is, photosensitivity indicates a range of a photosensitizer coated on a film, printing paper or the like, in response to individual colors of light.

The etched part 41 according to this embodiment is formed by cutting the upper edge of the second wavelength conversion part 40 downwardly. However, the position and number of the etched part 41 are not limited thereto. For example, at least one or more etched parts may be formed at the center of the second wavelength conversion part 40.

In addition, the etched part 41 may have various etched shapes such as a protrusion shape, like the protrusions 70 of FIGS. 10 and 11 by a patterning process. The etched size and etched angle of the etched part 41 may be varied in consideration of the light emission pattern of the light emitting device 20.

Meanwhile, in the present embodiment, the adhesive resin part 60 is formed on the first wavelength conversion part 30 and the second wavelength conversion part 40 is formed on the adhesive resin part 60. However, the invention is not limited thereto. Without the forming of the adhesive resin part 60, the second wavelength conversion part 40 may be directly formed on the first wavelength conversion part 30.

A method of manufacturing the light emitting device package having the above-described configuration will be described below.

First of all, the cavity 14 is formed within the substrate 10. The cavity 14 may be formed in the upper surface of the substrate 10 by a hole making process such as drilling or by stacking the sub-substrate 12 having a central hole portion on a flat upper surface of the sub-substrate 11.

In the case of the hole making process using drilling, the cavity 14 usually has a circular shape. In the case of the stacking of the sub-substrates, the cavity 14 may have various shapes such as a square shape, a quadrangular shape or the like corresponding to the shape of the central hole portion.

Thereafter, the light emitting device 20 may be mounted on the bottom surface of the cavity 14. The first wavelength conversion part 30 is formed by dispensing a transparent resin including a red phosphor to the cavity 14 while covering the light emitting device 20. Then, the second wavelength conversion part 40 is formed by coating a sheet-type phosphor film including a green phosphor on the first wavelength conversion part 30. The first and second wavelength conversion parts 30 and 40 are hardened at the same time, and thus a light emitting device package is manufactured.

The first wavelength conversion part 30 may be dispensed to the cavity 14 while allowing the upper portion of the cavity 14 to be empty, and then the second wavelength conversion part 40 may be coated thereon to fill the empty portion of the cavity 14. Alternatively, the first wavelength conversion part 30 may be formed to fill the entirety of the cavity 14, and then the second wavelength conversion part 40 may be coated thereon to be exposed outwardly of the cavity 14.

The second wavelength conversion part 40 may have a downwardly concave upper surface or an upwardly convex upper surface, taking into consideration the power of the light emitting device 20, the shape of the cavity 14, and the like, as necessary.

The plurality of protrusions 70 may be formed on the upper surface of the second wavelength conversion part 40 by patterning, thereby further enhancing light extraction efficiency.

According to another embodiment, instead of the protrusions 70, the plurality of light extraction enhancing parts 80, having a droplet shape and formed of a resin having high viscosity, may be formed on the upper surface of the second wavelength conversion part 40 while having a predetermined interval therebetween.

Here, the light extraction enhancing parts 80 may include a green phosphor or be formed of a transparent silicon.

According to another embodiment, since the second wavelength conversion part 40 has photosensitivity, the upper edge thereof may be etched by UV or the like to thereby form the etched part 41.

As stated above, the etched part 41 may have various etched shapes such as a protrusion shape, like the protrusions 70 formed by a patterning process. The etched size and etched angle of the etched part 41 may be varied in consideration of the light emission pattern of the light emitting device 20.

Here, in the case in which the light emitting device 20 is a blue LED chip, light produced in the light emitting device 20 transits the first wavelength conversion part 30 including the red phosphor and the second wavelength conversion part 40 including the green phosphor sequentially, to thereby produce white light.

In a case in which the power of the light emitting device 20 is altered, the amount of the first wavelength conversion part 30 is maintained and the thickness of the second wavelength conversion part 40 is adjusted to thereby alter color coordinates and color temperatures, whereby the characteristics of light to be finally emitted can be adjusted.

According to another embodiment, the cavity 14 may have a stepped multilayer structure by stacking the plurality of sub-substrates 12, 16 and 17 having central hole portions, whose diameters gradually increase in an upward direction, on the flat substrate 11.

The first wavelength conversion part 30 is formed by dispensing a transparent resin within the central hole portion of the lower sub-substrate 12 while covering the light emitting device 20. The thin adhesive resin part 60 is dispensed or coated within the central hole portion of the intermediate sub-substrate 16. The sheet-type second wavelength conversion part 40 is coated within the central hole portion of the upper sub-substrate 17 while covering the adhesive resin part 60. Here, the second wavelength conversion part 40 may have a thickness of 100 μm or less. Then, the lens part 50 is further provided on the substrate while covering the second wavelength conversion part 40.

As set forth above, in a light emitting device package according to embodiments of the invention, without the need for the configuration of a separate circuit with respect to individual LED chips, a first wavelength conversion part including a red phosphor and a second wavelength conversion part including a green phosphor are separately configured and the amount of resins used therein can be easily adjusted, whereby a simplified manufacturing process and enhanced CRI can be achieved.

Even in the case that chips have various levels of power applied thereto, the characteristics of light to be finally emitted may be easily adjusted by adjusting only the thickness of the second wavelength conversion part including the green phosphor and maintaining the amount of the red phosphor.

The manufacturing process may be simplified by preparing a stepped multilayer cavity structure and separately forming the first and second wavelength conversion parts.

While the present invention has been shown and described in connection with the embodiments, it will be apparent to those skilled in the art that modifications and variations can be made without departing from the spirit and scope of the invention as defined by the appended claims.

What is claimed is:

1. A light emitting device package comprising:
a substrate having a cavity therein;
a light emitting device mounted on a bottom surface of the cavity;
a first wavelength conversion part including a first phosphor for a wavelength conversion of light emitted from the light emitting device and covering the light emitting device within the cavity; and
a second wavelength conversion part including a second phosphor allowing for emission of light having a wavelength different to that of the first phosphor and formed as a sheet on the first wavelength conversion part.

2. The light emitting device package of claim 1, wherein the first phosphor of the first wavelength conversion part includes a red phosphor, and
the second phosphor of the second wavelength conversion part includes a green phosphor.

3. The light emitting device package of claim 1, wherein the first wavelength conversion part is disposed within the cavity, and
the second wavelength conversion part is exposed outside of an upper portion of the cavity.

4. The light emitting device package of claim 1, wherein the cavity has a stepped double layer structure,
the first wavelength conversion part is provided in a lower layer of the cavity, and
the second wavelength conversion part is provided in an upper layer of the cavity.

5. The light emitting device package of claim 1, wherein the light emitting device is a blue light emitting diode chip.

6. The light emitting device package of claim 1, wherein the second wavelength conversion part has a refraction index lower than that of the first wavelength conversion part.

7. The light emitting device package of claim 1, wherein the second wavelength conversion part has a downwardly concave upper surface.

8. The light emitting device package of claim 1, wherein the second wavelength conversion part has an upwardly convex upper surface.

9. The light emitting device package of claim 1, wherein the first wavelength conversion part and the second wavelength conversion part have an adhesive resin part provided therebetween.

10. The light emitting device package of claim 9, wherein the adhesive resin part has a refraction index lower than that of the first wavelength conversion part.

11. The light emitting device package of claim 1, wherein the second wavelength conversion part has a plurality of protrusions on an upper surface thereof.

12. The light emitting device package of claim 1, wherein the second wavelength conversion part has a plurality of droplet-shaped light extraction enhancing parts on an upper surface thereof.

13. The light emitting device package of claim 12, wherein the light extraction enhancing parts are formed of a green phosphor.

14. The light emitting device package of claim 12, wherein the light extraction enhancing parts are formed of a transparent silicon.

15. The light emitting device package of claim 1, wherein the second wavelength conversion part has an etched part formed by etching an upper edge thereof.

16. The light emitting device package of claim 1, wherein the cavity has an inclined inner wall.

17. The light emitting device package of claim 1, wherein the cavity has an inner wall serving as a light reflective surface.

18. The light emitting device package of claim 17, wherein the inner wall of the cavity is further coated with a reflective material.

19. The light emitting device package of claim 1, further comprising a lens part provided on the substrate while covering the second wavelength conversion part.

20. A method of manufacturing a light emitting device package, the method comprising:
preparing a substrate having a cavity therein and mounting a light emitting device within the cavity;
forming a first wavelength conversion part within the cavity by mixing a first phosphor with a transparent resin such that the first wavelength conversion part covers the light emitting device and converts a wavelength of light emitted from the light emitting device;
forming a second wavelength conversion part on the first wavelength conversion part by coating a sheet-type phosphor film including a second phosphor allowing for emission of light having a wavelength different to that of the first phosphor; and
hardening the first and second wavelength conversion parts at the same time.

21. The method of claim 20, wherein the first wavelength conversion part includes a red phosphor, and
the second wavelength conversion part includes a green phosphor.

22. The method of claim 20, wherein the cavity is formed in an upper surface of the substrate by a hole making process using drilling.

23. The method of claim 20, wherein the cavity is formed by stacking a second sub-substrate having a central hole portion on a flat upper surface of a first sub-substrate.

24. The method of claim 20, wherein the cavity has a stepped double layer structure formed by stacking a second sub-substrate having a central hole portion on a flat upper surface of a first sub-substrate and stacking a third sub-substrate having a central hole portion greater than that of the second sub-substrate on the second sub-substrate.

25. The method of claim 24, wherein the first wavelength conversion part is dispensed to a lower layer of the cavity formed by the second sub-substrate, and
the sheet-type second wavelength conversion part is coated to cover the first wavelength conversion part in an upper layer of the cavity formed by the third sub-substrate.

26. The method of claim 20, wherein the first wavelength conversion part is formed within the cavity, and
the second wavelength conversion part is disposed outside the cavity while covering an upper surface of the first wavelength conversion part.

27. The method of claim 20, wherein the light emitting device is a blue light emitting diode chip.

28. The method of claim 20, wherein the forming of the second wavelength conversion part comprises causing an upper surface of the phosphor film to be downwardly concave.

29. The method of claim 20, wherein the forming of the second wavelength conversion part comprises causing an upper surface of the phosphor film to be upwardly convex.

30. The method of claim 20, further comprising forming an adhesive resin part on the first wavelength conversion part prior to the forming of the second wavelength conversion part.

31. The method of claim 20, further comprising forming a plurality of protrusions by patterning an upper surface of the second wavelength conversion part after the forming of the second wavelength conversion part.

32. The method of claim 20, further comprising forming a plurality of light extraction enhancing parts having a droplet shape on an upper surface of the second wavelength conversion part by a coating process after the forming of the second wavelength conversion part.

33. The method of claim 20, further comprising forming an etched part by etching an upper edge of the second wavelength conversion part by a UV treatment after the forming of the second wavelength conversion part.

34. The method of claim 20, further comprising providing a lens part on the substrate.
